(19) United States
(12) Patent Application Publication
(10) Pub. No.: US 2011/0085371 A1
(43) Pub. Date: Apr. 14, 2011

(54) APPARATUS OF LOW POWER DUAL WORD LINE SIX-TRANSISTOR SRAMS

(76) Inventor: Michael C. Wang, Irvine, CA (US)

(21) Appl. No.: 12/577,155

(22) Filed: Oct. 10, 2009

(51) Int. Cl. G11C 11/00; G11C 7/00

(52) U.S. Cl. 365/156; 365/189.16

(57) ABSTRACT

A six-transistor SRAM cell with dual word line and dual bit line is provided. Each word line is used to separately control an access transistor of the SRAM cell. A six-transistor SRAM cell with dual word line and a single bit line is also provided. The dual word line SRAM cells reduce word line and bit line switching power, and thus reduces the overall power consumption.

### FIELD OF THE INVENTION

The present invention relates to a static random access memory. In particular, to a six-transistor static random access memory cell.

### BACKGROUND

Static random access memory (SRAM) is an important memory device for storing data on chip. A typical SRAM cell is constructed with six transistors. In this paper, “6T SRAM” and “six-transistor SRAM” are interchangeably used. In the same manner, “7T SRAM” means “seven-transistor SRAM”, etc. Advantages of SRAM include its fast read/write speed, and meta-stability—the data bit and its complement bit faithfully “lock” each other to a stable state. However, the continuing technology scaling requires future generations of SRAM cell to be small and power efficient—both qualities are difficult to achieve by simply scaling the size of transistors in the nanometer regime.

As technology scaling continues, power consumption has becomes a major concern to circuit designers. According to Moore's Law, the number of transistors built on a single chip doubles every two years. If the power consumption due to each individual transistor does not scale down with the transistor's size, the power consumption of the whole chip will continue to increase, which leads to higher chip temperature and thus degrades performance due to low electron/hole mobility at high temperature.

The two main components of the power consumption of a transistor are switching power and leakage power. The switching power occurs when the transistor is charging the output capacitor to V_{DD}. The leakage power arises from the source to drain diffusion current when the gate of the transistor is off. The switching component can be reduced quadratically by simply reducing V_{DD}. In the past, supply voltage scaling has been used to reduce power consumption. However, supply voltage scaling is limited by two factors. First, a small V_{DD} causes a huge switching delay, which is proportional to leakage power. Second, some circuits, such as SRAM, have a minimum noise margin requirement, which cannot be met by a very small V_{DD}.

One technique to reduce the SRAM power consumption is by adding extra “control” transistors. For example, 7T SRAM (See R. Aly, M. Faisal, and A. Bayoumi, “Novel 7T SRAM cell for low power cache design”, Proc. IEEE SOC Conf, 2005, pp. 171-174), 8T SRAM (See S. K. Jain and P. Agarwal, “A low leakage and SNM free SRAM cell design in deep sub-micron CMOS technology”, Proc. 19th International Conference on VLSI Design held jointly with the 5th International Conference on Embedded Systems Design, 2006, pp. 495-498), and 9T SRAM (See Z. Liu and V. Kursun, “Characterization of a Novel Nine-Transistor SRAM Cell”, IEEE Transactions on VLSI Systems, 2008, vol. 16, pp. 488-492) are proposed. While these designs are innovative, they incur significant area overhead by using extra transistors.

### SUMMARY

It is an object of the present invention to provide new architectures to reduce power consumption occurred in a 6T SRAM cell without consuming extra area.

According to a first aspect of the present invention there is provided a 6T SRAM cell having two independently controlled word lines. This 6T SRAM operating scheme, enabled by the addition of the second word line, provides significant power reduction by reducing the amount of switching power on bit lines.

According to a second aspect of the present invention there is provided a 6T SRAM cell having dual word line and a single bit line that achieves smaller area while retaining all of the power saving advantages.

For a small penalty in delay, 6T SRAM with dual word line SRAMs are attractive alternatives as memory storages for applications that do not require high clock frequency.

In order to facilitate an understanding of the invention, the preferred embodiments of the invention are illustrated in the drawings, and a detailed description thereof follows. It is not intended, however, that the invention be limited to the particular embodiments described or to use in connection with the apparatus illustrated herein.

### BRIEF DESCRIPTION OF THE DRAWINGS

FIG. 1 shows a schematic diagram of a traditional 6T SRAM cell.

FIG. 2 shows a layout in 65 nm technology of the traditional 6T SRAM cell of FIG. 1.

FIG. 3 shows a schematic diagram of a 6T SRAM cell with dual word line and dual bit line of one embodiment of the present invention.

FIG. 4 shows a layout of a 6T SRAM cell with dual word line and dual bit line in 65 nm technology.

FIG. 5 shows schematic diagram of a 6T SRAM cell with dual word line and a single bit line of another embodiment of the present invention.

FIG. 6 shows a layout of a 6T SRAM cell with dual word line and single bit line in 65 nm technology.

FIG. 7 shows a noise margin diagram for the traditional 6T SRAM of FIG. 1.

FIG. 8 shows a noise margin diagram for the 6T SRAM cell with dual word line of FIGS. 3 and 5.

FIG. 9 shows power consumption for different 6T SRAMs of FIGS. 1, 3 and 5.

### DETAILED DESCRIPTION

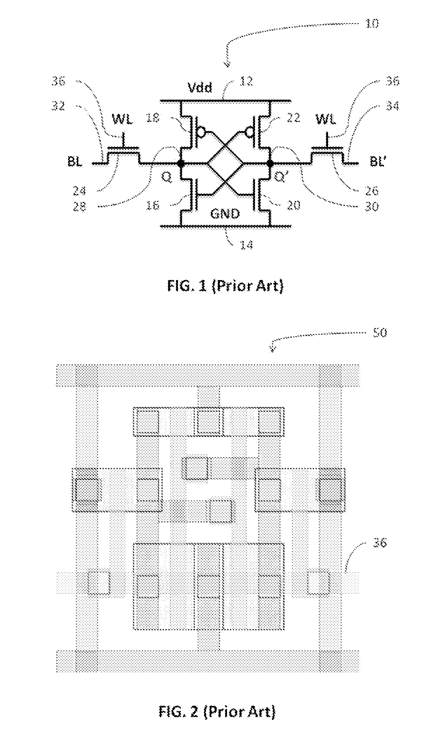

FIG. 1 is a schematic diagram of a conventional six-transistor SRAM cell 10 (hereafter also referred to as 6T1W2B, which stands for 6 Transistors, 1 Word line, and 2 Bit lines). Both storage nodes 28, 30 (also denoted as Q, Q′) are statically tied to either V_{DD} 12 or GND 14 (hence the prefix static or S). Two inverters (one configured by a NMOS 16 and a PMOS 18, another configured by a NMOS 20 and a PMOS 22) are cross-coupled—the output of each inverter is the input of the other inverter. Since two cross-coupled inverters constitute a ring oscillator, the storage nodes will settle in a stable state (note that a ring oscillator with odd number of inverters will oscillate). Each storage node is also coupled to one of bit line BL 32 and bit line BL′ 34, through one of the access transistors 24, 26. A single word line WL 36 is used to control both access transistors 24, 26. Through the access transistors 24, 26, data can be read from or written into the storage nodes Q 28, Q′ 30.

Typically, an SRAM device can perform the following actions: hold, read, and write. How the 6T SRAM cell 10 of FIG. 1 performs the above actions is described hereafter.

Hold: when an SRAM cell 10 is not being written or read, it is in the “hold” state. The word line WL 36 is asserted to a low voltage, for example, GND 14, to turn off access transistors 24, 26. SRAM cell 10 is now simply a two-transistor ring oscillator. It is easy to see that the storage nodes Q 28, Q′ 30 “lock” each other to the voltage of one of the supply rails (V_{DD} 12 or GND 14). Deviations from the supply rail voltage will be eliminated quickly.

Read: before reading a value from the storage nodes Q 28, Q′ 30, both bit line BL 32 and bit line BL′ 34 are pre-charged to a high voltage, for example, V_{DD} 12. The word line WL 36 is then asserted to a high voltage, for example, V_{DD} 12. The storage node that stores a high voltage or “1” will stay at “1” since it is connected to a pre-charged bit line. The storage node that stores a “0” is statically connected to GND 14 and will drain the charges on the bit line, which means that the bit line has just read a “0”. Note that at the instant when the word line WL 36 is turned on, the storage node that stores a “0” will jump to an intermediate voltage because there is now a current path from the bit line to GND 14. The intermediate voltage is determined by voltage dividers constructed by one of the access transistors 24, 26 and the NMOS transistors 16, 20 of the cross-coupled inverters. Since the storage nodes Q 28, Q′ 30 are coupled, it is preferably that the intermediate voltage not to jump too high, otherwise it will invert the data stored at the other storage node. Therefore, the NMOS transistors 16, 20 of the cross-coupled inverters are made larger than the access transistors 24, 26 to ensure that the intermediate voltage does not flip the content of the other storage node.

Write: before writing a value, bit line BL 32 will be asserted to a value desired to be written while bit line BL′ 34 will be asserted to a value opposite to the value desired to be written. For example, in FIG. 1, if a “0” is desired to be written, then bit line BL 32 will be asserted to a low voltage, for example, GND 14, and bit line BL′ 34 will be asserted to a high voltage, for example, V_{DD} 12. At the instant when the word line 36 is asserted to a high voltage, for example, V_{DD} 12, to turn on the access transistors 24, 26, storage node 28 will jump to an intermediate voltage. However, as discussed in the previous section, the size of NMOS transistors 16, 20 of the cross-coupled inverters is preferably to be larger than the access transistors 24, 26. As a result, the intermediate voltage will not jump too high to invert the content of the other storage node. Therefore, the write operation has to be performed through the side with storage node at “1” and bit line pre-charged to a low voltage, for example, GND 14. In this case, when the word line WL 36 is turned on, there will be a current path between the supply rail V_{DD} 12 and the bit line which is pre-charged to a low voltage, for example, GND 14, via the PMOS transistor of the cross-coupled inverter and one of the access transistors. These transistors are preferably sized so that the intermediate voltage will be low enough to flip the content of the other storage node, thus achieving a write operation. In other words, access transistors 24, 26 have to be stronger than the PMOS transistors 18, 22 of the cross-coupled inverters.

As the above paragraphs demonstrate, the driving strength of the transistors of the conventional 6T SRAM cell 10 can be ordered as follows: NMOS transistors 16, 20 of the cross-coupled inverters>access transistors 24, 26>PMOS transistors 18, 22 of the cross-coupled inverters. A layout 50 of the 6T SRAM cell 10 of FIG. 1 is illustrated in FIG. 2.

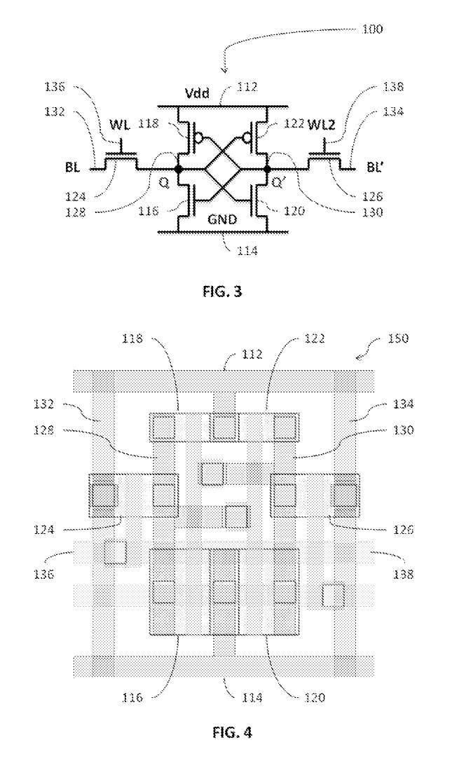

FIG. 3 shows the schematic diagram of a dual word lines 6T SRAM cell 100 of one embodiment of the present invention (hereafter also referred to as 6T2W2B).

Similar to 6T1W2B, the 6T2W2B cell has a first inverter configured by a NMOS 116 and a PMOS 118, and a second inverter configured by a NMOS 120 and a PMOS 122. Storage node Q128 of the first inverter coupled to the input (gates of NMOS 120 and PMOS 122) of the second inverter. Also, storage node Q′ 130 of the second inverter coupled to the input (gates of NMOS 116 and PMOS 118) of the first inverter. Therefore, the first inverter and the second inverter are cross-coupled. When SRAM cell 100 is in a hold state, the first inverter and the second inverter can form a ring oscillator, the storage nodes Q 128 and Q′ 130 will settle in a stable state. Therefore, Q 128 and Q′ 130 can store data for SRAM cell 100.

Storage node Q 128 is coupled to bit line BL 132 through access transistor 124. Similarly, storage node Q′ 130 is coupled to bit line BL′ 134 through access transistor 126.

For write operation, data on bit line BL 132 can be written into storage node Q 128 through access transistor 124, and data on bit line BL′ 134 can be written into storage node Q′ 130 through access transistor 126. For read operation, data is always read from the storage node Q 128 to bit line BL 132.

A first word line WL 136 is used to control access transistor 124 by coupling to the gate of access transistor 124. A second word line WL2 138 is used to control access transistor 126 by coupling to the gate of access transistor 126. In this configuration, each one of access transistors 124, 126 is controlled separately by word line WL 136, word line WL2 138.

SRAM cell 100 can always be read/written from one side, for example, a write operation is done primarily by forcing a “0” into the SRAM cell 100 from one side, and a read operation is done primarily by draining charges from bit line 132 to a GND 114. By having both word line WL 136 and word line WL2 138, the access transistor that is not active during read/write operation can be turned off. In other words, utilizing both word line WL 136, word line WL2 138 to independently control access transistors 124, 126 provides a novel power-saving operating scheme to a 6T SRAM.

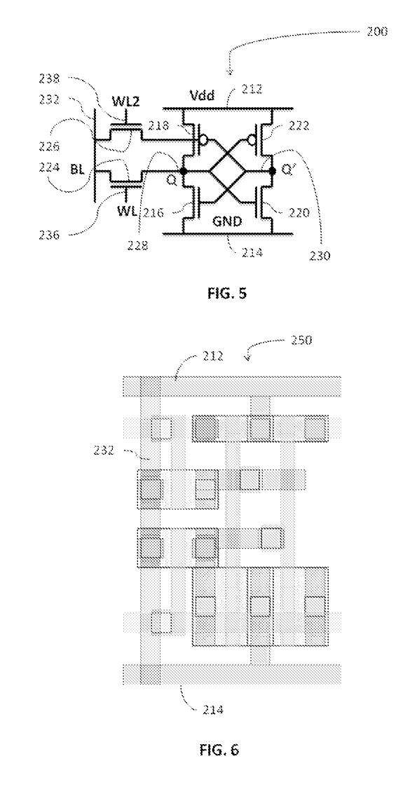

In a 4T SRAM design, a single word line cannot realize the SRAM functionalities. Therefore, a dual word line design has been proposed. (See A. A. Mazreah, T. Manzuri Shalmani, H. Barati, and A. Barati, “A Novel Four-Transistor SRAM Cell with Low Dynamic Power Consumption”, Proc World Academy of Science, Engineering and Technology, 2008) Nevertheless, the novelty of utilizing dual word line in a 6T SRAM not only provides a power-saving scheme, but also grants the ability to shrink cell area by merging both bit lines into a single bit line, which is not possible for the 4T SRAM. The operations of the 6T SRAM cell 100 with dual word line and dual bit line (6T2W2B) will now be elaborated. A 6T SRAM cell 200 (shown in FIG. 5) with dual word line and single bit line (hereafter referred to as 6T2W1B) will be elaborated later.

Hold: both word line WL 136 and word line WL2 138 are asserted to a low voltage, for example, GND 114, to turn off access transistors 124, 126 so that the cross-coupled inverters form a two-transistor ring oscillator.

Read: pre-charge bit line BL 132 to a high voltage, for example, V_{DD} 112, then assert word line WL 136 to a high voltage, for example, V_{DD} 112, and turn access transistor 126 off by asserting the second word line WL2 138 to a low voltage, for example, GND 114. This implies that read operation is always performed from bit line BL 132 (see FIG. 3). If storage node Q 128 is at “1”, bit line BL 132 will remain at “1”. If storage node Q 128 is at “0”, bit line BL 132 will be discharged to GND 114. Thus, the information at storage node Q 128 is “read” onto bit line BL 132.

Write: given how SRAM is sized, writing a “1” into storage node Q 128 is accomplished by writing a “0” into its complementary storage node Q′ 130. To write a “1” into storage node Q 128, WL2 138 is asserted to a high voltage, for example, V_{DD} 112, and word line WL 136 is asserted to a low voltage, for example, GND 114, to turn off access transistor 124. Next, line BL′ 134 is asserted to a low voltage, for example, GND 114, so that storage node Q′ will be pulled to “0”, which will then pull storage node Q 128 to “1”. Since access transistor 124 is turned off, there is nothing that will prevent storage node Q 128 from being pulled up to a “1”. To write a “0” into storage node Q 128 can be done similarly. Word line WL 136 is asserted to a high voltage, for example, V_{DD} 112, and word line WL2 138 is asserted to a low voltage, for example, GND 114, then bit line BL 132 is asserted to a low voltage, for example, GND 114, so that storage node Q 128 will be pulled to “0”.

Even though this setup requires both word line WL 136 and word line WL2 138, only one is asserted during a read or a write operation. Therefore, the 6T SRAM cell 100 with dual word line (6T2W2B) does not incur extra dynamic power consumption on word line WL 136 and word line WL2 138. The advantage of this configuration comes from the reduction of bit line switching. In a read operation, only bit line BL 132 needs to be pre-charged to a high voltage, for example, V_{DD} 112 (while in the traditional 6T1W2B, both bit line BL 32 and bit line BL′ 34 need to be pre-charged). In a write operation, neither bit line BL 132 nor bit line BL′ 134 will be asserted to a high voltage (while in the traditional 6T1W2B, one of bit line BL 32 or bit line BL′ 34 will be asserted to a high voltage).

The layout of the 6T SRAM cell 100 with dual word line and dual bit line of FIG. 3 is shown in FIG. 4. By comparing FIG. 4 to FIG. 2, it is easy to see that the layout 150 of the dual word line design does not incur extra area overhead because the extra word line WL 138 can be easily routed through the SRAM cell as illustrated in FIG. 4.

The action done to bit line BL 132 and bit line BL′ 134 during read/write operations will now be described. For a read operation, bit line BL 132 is pre-charged to a high voltage, for example, V_{DD} 112; for a write “0” operation, bit line BL 132 is asserted to a low voltage, for example, GND 114, and for a write “1” operation, bit line BL′ 134 is asserted to a low voltage, for example, GND 114. Note that in any case, only one of bit line BL 132 or bit line BL′ 134 is active; the other bit line is in the “don't care” state. This suggests that it is possible to merge both bit line BL 132 and bit line BL′ 134 into a single bit line BL 232, as shown in FIG. 5, which is a schematic diagram of a 6T SRAM cell 200 with dual word line and single bit line (hereafter also referred to as 6T2W1B) of another embodiment of the present invention.

Similar to 6T2W2B, the 6T2W1B cell has a first inverter configured by a NMOS 216 and a PMOS 218, and a second inverter configured by a NMOS 220 and a PMOS 222. The storage node Q 228 of the first inverter coupled to the input (gates of NMOS 220 and PMOS 222) of the second inverter. Also, the storage node Q′ 230 of the second inverter coupled to the input (gates of NMOS 216 and PMOS 218) of the first inverter. Therefore, the first inverter and the second inverter are cross-coupled. When SRAM cell 200 is in a hold state, the first inverter and the second inverter can form a ring oscillator, the storage nodes Q 228 and Q′ 230 will settle in a stable state. Therefore, Q 228 and Q′ 230 can store data for SRAM cell 200

Storage node Q 228 is coupled to bit line BL 232 through access transistor 224. Similarly, storage node Q′ 230 is coupled to bit line BL 232 through access transistor 226.

Through access transistor 224, data stored on storage node Q 228 can be read from storage node Q 228 to bit line BL 232. Also, data on bit line BL 232 can be written into storage node Q 228 through access transistor 224. Similarly, data stored on storage node Q′ 230 can be read from storage node Q′ 230 to bit line BL 232 through access transistor 226. Also, data on bit line BL 232 can be written into storage node Q′ 230 through access transistor 226.

A word line WL 236 is used to control access transistor 224 by coupling to the gate of access transistor 224. A second word line WL2 238 is used to control access transistor 226 by coupling to the gate of access transistor 226. In this configuration, each one of the access transistors 224, 226 is controlled separately by word line WL 236 and word line WL2 238.

The operating scheme for 6T SRAM cell 200 with dual word line and single bit line (6T2W1B) shown in FIG. 5 will now be described.

Hold: both word line WL 236 and word line WL2 238 are asserted to a low voltage, for example, GND 214, to turn off access transistors 224, 226 so that the cross-coupled inverters form a two-transistor ring oscillator.

Read: pre-charge bit line BL 232 to a high voltage, for example, V_{DD} 212, then assert word line WL 236 to a high voltage, for example, V_{DD} 212, and word line WL2 238 to a low voltage, for example, GND 214. If the storage node Q 228 is at “1”, BL will remain at “1”. If storage node Q 228 is at “0”, bit line BL 232 will be discharged to GND 214. Thus the information at storage node Q 228 has been “read” onto bit line BL 232.

Write: To write a “1” into storage node Q 228, word line WL2 238 is asserted to a high voltage, for example, V_{DD} 212, and word line WL 236 is asserted to a low voltage, for example, GND 214. Next, bit line BL 232 is asserted to a low voltage, for example, GND 214, so that storage node Q′ 230 will be pulled to “0”, which will then pull storage node Q 228 to “1”. Since word line WL 238 is asserted to “0” to turn off access transistor 224, there is nothing that will prevent storage node Q 228 from being pulled up to “1”. To write a “0” into storage node Q 228 is done similarly; word line WL 236 is asserted to a high voltage, for example, V_{DD} 212, and word line WL2 238 is asserted to a low voltage, for example, GND 214, then bit line BL 232 is asserted to a low voltage, for example, GND 214, so that storage node Q 228 will be pulled to “0”.

The 6T SRAM cell 200 with dual word line and a single bit line can further reduce cell area. As shown in FIG. 6, both access transistors 224, 226 can be sit in the same side of the 6T SRAM cell 250 to reduce the overall width of the layout of the cell 6T SRAM cell 250. This benefit is exclusive to the single bit line design of a 6T SRAM 200, because both access transistors 224, 226 share the same bit line BL 232.

Simulation results for the three SRAM designs (6T1W2B, 6T2W2B, 6T2W1B) that discussed previously are presented in Table 1. The extraction of three important metrics of an SRAM design: noise margins, power, and delays will be described hereafter.

TABLE 1
Summary of three 6T SRAM cell designs

| | SRAM | | |
|---|---|---|---|
| | 6T1W2B | 6T2W2B | 6T2W1B |
| Area (um²) | 1.6383 | 1.6383 | 1.4413 |

Write 0/1 Scheme

| | | | |
|---|---|---|---|
| WL | Tie to 1 | Tie to 1/0 | Tie to 1/0 |
| WL2 | — | Tie to 0/1 | Tie to 0/1 |
| BL | Tie to 0/1 | Tie to 0/X | Tie to 0 |
| BL′ | Tie to 1/0 | X/Tie to 0 | — |

Read 0/1 Scheme

| | | | |
|---|---|---|---|
| WL | Tie to 1 | Tie to 1 | Tie to 1 |
| WL2 | — | Tie to 0 | Tie to 0 |
| BL | PC to 1 | PC to 1 | PC to 1 |
| BL′ | PC to 1 | X | — |

Hold 0/1 Scheme

| | | | |
|---|---|---|---|
| WL | Tie to 0 | Tie to 0 | Tie to 0 |
| WL2 | — | Tie to 0 | Tie to 0 |
| BL | X | X | X |
| BL′ | X | X | — |

Noise Margin (V)

| | | | |
|---|---|---|---|
| Write 0 | 0.385 | 0.319 | 0.319 |
| Read 1 | 0.15 | 0.15 | 0.15 |
| Read 0 | 0.15 | 0.304 | 0.304 |
| Hold 1 | 0.304 | 0.304 | 0.304 |
| Hold 0 | 0.304 | 0.304 | 0.304 |

Operation Delay (ps)

| | | | |
|---|---|---|---|
| Write 1 | 86.6 | 99.1 | 99.1 |
| Write 0 | 31.9 | 51.1 | 51.1 |
| Read 0 | 520.0 | 520.0 | 521.0 |

Extracted Average Operating Power Consumption (uW)

| | | | |
|---|---|---|---|
| Write 1 | 6.09 | 6.03 | 6.03 |
| Write 0 | 6.09 | 6.03 | 6.03 |
| Read 1 | 25.4 | 0.0195 | 0.0259 |
| Read 0 | 25.4 | 25.4 | 25.5 |
| Hold 1 | 0.0237 | 0.0237 | 0.0237 |
| Hold 0 | 0.0237 | 0.0237 | 0.0237 |

Calculated Switching Power Consumption (uW)

| | | | |
|---|---|---|---|
| Write 1 | 100 | 50 | 50 |
| Write 0 | 100 | 50 | 50 |
| Read 1 | 150 | 100 | 100 |
| Read 0 | 150 | 100 | 100 |

Note:
PC stands for pre-charge;
X stands for don't care

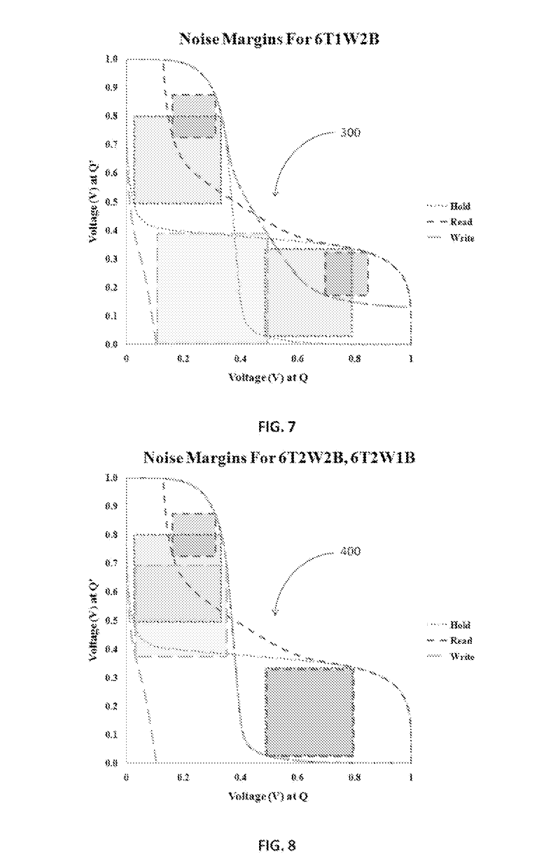

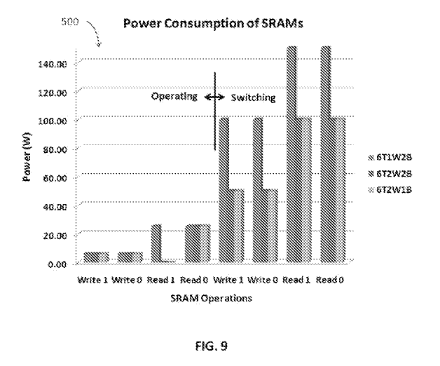

Noise margin extraction will now be described. Noise margin is a measurement of SRAM's tolerance to voltage variations. During a read/hold operation, the SRAM cell is preferably to be as robust as possible so that a sudden disturbance will not change the content in the storage nodes. For example, a read noise margin of 0.4V means that during a read operation, if one of the storage nodes (Q or Q′) changes by less than 0.4V, then, after the read operation, the contents of Q and Q′ will remain the same, and any disturbance to the voltage in the cell will be eliminated. Therefore, a larger read/hold noise margin is preferred. During a write operation, the situation is reversed; the contents of Q and Q′ are preferably be easily switched. Therefore, the write noise margin (more commonly referred to as the “write margin”) can be defined as the range of voltage disturbances that will flip the content of the storage nodes. For example, if a write margin is 0.5V, then a range of at least 0.5V disturbance in the storage nodes (say 0.1V to 0.6V) will cause their content to flip, thus achieving a write operation. The noise margins graphs for all three SRAMs discussed in this paper are shown in FIGS. 7 and 8.

The exact value of noise margins are extracted by first finding the largest square that fits between the curves traced out by the cross-coupled inverter, and then measuring the length of the square and convert it to voltage, as shown in FIGS. 7 and 8. The noise margins for these SRAMs are shown in Table 1. Based on simulation results, 6T SRAM designs with dual word line (6T2W2B, 6T2W1B) suffer 17% reduction in write margin for writing, but gain 103% more read noise margin for reading a “0”.

Delay extraction will now be described. SRAM delays usually are defined as the time it takes to read or write a value from an SRAM cell. When a node is switching, delay is measured as the time difference between 10% and 90% of the voltage swing. For example, if node A is pulled from 0V to 1V, then the delay is the time it takes for node A to go from 0.1V to 0.9V.

For example, of that all the buses (bit line and word line) have 50 fF capacitance and all storage nodes have 1 fF capacitance, therefore, it takes much less effort to switch storage nodes than to switch bit line. This is why, in general, delays for a write operation are smaller than delays for a read operation in SRAMs, because writing into a cell is the same as switching the storage node, and reading from a cell is the same as switching the bit line. Note that for a read operation, since the bit line are pre-charged to V_{DD}, there is no significant current flow and voltage changes across the access transistor if the cell contains a “1”. Therefore, read “1” delay is not defined. Based on simulation results, the 6T SRAMs with dual word line (6T2W2B and 6T2W1B) incur an average 37% increase in write delay (14% increase for writing “1”, and 60% increase for writing “0”) compared with the traditional single word line 6T SRAM (6T1W2B). There is no significant difference in read delay.

Power extraction will now be described. In an SRAM operation, power is consumed in two phases: the setup phase and the operation phase.

Energy consumed during the setup phase is dominated by pre-charging/discharging various buses such as bit lines and word lines. Using the formula E_{bus}=C_{bus}V_{bus}V_{DD}, in which C_{bus} is the bus capacitance and V_{bus} is the change in bus voltage, the energy drawn from the supply by the bus can be calculated. From this information, the average power of an SRAM operation can be calculated by dividing the clock period.

The power consumption for the setup phase is reported as “Calculated Switching Power Consumption” in Table 1. In the example of Table 1, 50 fF capacitance is applied for all buses (including supply rails for from SRAMs that utilizes multiple voltage supplies).

Power consumed during the operation phase is dominated by active power and leakage power. Active power is the power consumed when both pull-up and pull-down network are active, creating a direct current path from V_{DD} to ground. Leakage power is the power consumed when charges “leak” through a transistor that is off. Measuring the active and leakage components of power consumption separately is very difficult. Therefore, the aggregated power consumption by using the .PRINT POWER command in HSPICE is measured, which will provide the total power drawn from all voltage sources. The result is shown as “Extracted Average Operating Power Consumption” in Table 1. Based on simulation results, 6T SRAMs with dual word line (6T2W2B and 6T2W1B) achieves an average 17% reduction in operating power consumption and, most importantly, a 42% reduction in bit line and word line switching power consumption compared with the traditional single word line 6T SRAM (6T1W2B).

FIG. 9 shows the operating power consumption and switching power consumption of 6T1W2B, 6T2W2B, and 6T2W1B categorized by SRAM operations.

Various modifications and alternative embodiments such as would ordinarily occur to one skilled in the art to which the invention relates are also contemplated and included within the scopes of the invention described and claimed herein.

We claim:

1. A six-transistor SRAM cell comprising:
a first inverter having an input and an output;
a second inverter having an input and an output, the input of the second inverter coupled to the output of the first inverter, the input of the first inverter coupled to the output of the second inverter;
a first pass transistor having a gate, a first terminal and a second terminal, the first terminal of the first pass transistor coupled to the output of the first inverter, the second terminal of the first pass transistor coupled to a first bit line, and the gate of the first pass transistor coupled to a first word line; and
a second pass transistor having a gate, a first terminal and a second terminal, the first terminal of the second pass transistor coupled to the output of the second inverter, the second terminal of the second pass transistor coupled to a second bit line, and the gate of the second pass transistor coupled to a second word line.

2. The six-transistor SRAM cell of claim 1, wherein the first word line and the second word line are controlled independently.

3. The six-transistor SRAM cell of claim 1, wherein the first terminal of the first pass transistor is a drain and the second terminal of the first pass transistor is a source.

4. A six-transistor SRAM cell comprising:
a first inverter having an input and an output;
a second inverter having an input and an output, the input of the second inverter coupled to the output of the first inverter, the input of the first inverter coupled to the output of the second inverter;
a first pass transistor having a gate, a first terminal and a second terminal, the first terminal of the first pass transistor coupled to the output of the first inverter, the second terminal of the first pass transistor coupled to a bit line, and the gate of the first pass transistor coupled to a first word line; and
a second pass transistor having a gate, a first terminal and a second terminal, the first terminal of the second pass transistor coupled to the output of the second inverter, the second terminal of the second pass transistor coupled to the same bit line as the first pass transistor, and the gate of the second pass transistor coupled to a second word line.

5. The six-transistor SRAM cell of claim 4, wherein the first word line and the second word line are controlled independently.

6. The six-transistor SRAM cell of claim 4, wherein the first terminal of the first pass transistor is a drain and the second terminal of the first pass transistor is a source.

7. A method for writing a “1” to a six-transistor SRAM cell comprising the steps of:
asserting a low voltage to a first word line of the six-transistor SRAM cell;
asserting a high voltage to a second word line of the six-transistor SRAM cell; and
asserting a low to a bit line of the six-transistor SRAM cell.
